(19) United States
(12) Patent Application Publication
(10) Pub. No.: US 2016/0014920 A1
(43) Pub. Date: Jan. 14, 2016

(54) DISPLAY SUPPORTING DEVICE

(71) Applicant: BENQ Corporation, Taipei (TW)

(72) Inventors: Yu-Ming Hsu, Taipei (TW); LIU-YI Huang, Taipei (TW)

(73) Assignee: BENQ Corporation, Taipei (TW)

(21) Appl. No.: 14/753,188

(22) Filed: Jun. 29, 2015

(30) Foreign Application Priority Data
Jul. 10, 2014 (TW) 103123772

(51) Int. Cl. H05K 5/02; F16M 11/10; F16M 11/04

(52) U.S. Cl. CPC H05K 5/0234; F16M 11/046; F16M 11/10

(57) ABSTRACT

The present invention provides a display supporting device for supporting a display module. The display supporting device includes a stand, a moving part, and an indicating device. The moving part is disposed on the stand and movable between a first position and a second position for connecting the display module with the stand. The indicating device is disposed on the stand and indicates the position of the moving part relative to the stand. The indicating device is able to record the rotating angle or moving distance of the moving part. The display module can be adjusted back to a recorded angle or position in accordance with the indicating device when the display module changes its angle or position.

### BACKGROUND OF THE INVENTION

1. Field of the Invention

This invention generally relates to a display supporting device. More particularly, this invention relates to a display supporting device for supporting a display module.

2. Description of the Prior Art

Display devices are commonly used consumer products. In addition to being a necessary output apparatus of a computer, the watching of television programs and the playing of video games also need display devices to output images.

A display device usually stands on a desk, a cabinet, or a table by a stand for a user to watch. Conventionally, the user would adjust the display device in the height, the pitch angle, the bilateral angel, etc., on account of the user's form, habits, purpose of use, and other factors. However, a readjustment has to be made if the display device has been adjusted due to someone else's use or has a position change caused by unintentional contacts. Though the adjustment itself is not difficult, it dose take time for the user to make the display device at a satisfied position and it is inconvenient for the user. Therefore, reducing the user's adjusting time and bringing the display device back to the user's customary position promptly is an issue to be solved.

### SUMMARY OF THE INVENTION

It is an object of the present invention to provide a display supporting device to reduce the user's adjusting time and bring the display device back to the user's customary position promptly.

The display supporting device of the present invention is for supporting a display module. The display supporting device includes a stand, a moving part, and an indicating device. The moving part is disposed on the stand, wherein the moving part is movable between a first position and a second position relative to the stand for connecting the display module with the stand. The indicating device is disposed on the stand for indicating the position of the moving part relative to the stand. The indicating device is able to record the rotating angle or moving distance of the moving part; the display module can be adjusted back to a recorded angle or position in accordance with the indicating device when the display module changes its angle or position.

The moving part is movable along a straight line relative to the stand. The moving part is movable along a curved line relative to the stand. The moving part is rotatable relative to the stand. The indicating device includes a guide groove and an indicating part. The guide groove is disposed on the stand along a moving path of the moving part relative to the stand. The indicating part is disposed in the guide groove, wherein the indicating part is movable along the guide groove and stops at a third position for indicating the position of the moving part relative to the stand and recording the indicated angle or position of the display module corresponding to the first position. The guide groove further includes graduations.

The indicating device includes a guide rail and an indicating part. The guide rail is disposed on the stand along a moving path of the moving part relative to the stand. The indicating part is sleeved on the guide rail, wherein the indicating part is movable along the guide rail and stops at a third position for indicating the position of the moving part relative to the stand and recording the indicated angle or position of the display module corresponding to the first position. The guide rail further includes graduations.

The indicating device includes a plurality of sockets and an indicating part. The plurality of sockets are disposed on the stand along a moving path of the moving part relative to the stand. The indicating part can be inserted in one of the sockets for indicating the position of the moving part relative to the stand and recording the indicated angle or position of the display module corresponding to the first position.

The indicating device includes a magnetic bar and an indicating part. The magnetic bar is disposed on the stand along a moving path of the moving part relative to the stand. The indicating part has magnetic permeability, wherein the indicating part can be magnetically drawn on the magnetic bar and stops at a third position for indicating the position of the moving part relative to the stand and recording the indicated angle or position of the display module corresponding to the first position. The magnetic bar further includes graduations.

The moving part further includes a mark disposed adjacent to the indicating device, wherein the indicating device takes the mark as a reference to indicate the position of the moving part relative to the stand.

It is to be understood that the above description and the embodiments below are merely illustrative and are not to be considered limitations to the scope of the invention.

### BRIEF DESCRIPTION OF THE DRAWINGS

FIG. 1A is a schematic view of a preferred embodiment of the present invention;

FIG. 1B is a schematic view of an embodiment of the indicating part of the present invention;

FIGS. 1C-3 are schematic views of an embodiment of the present invention showing the indicating part disposed in the guide groove;

FIGS. 4A-6 are schematic views of different embodiments of the present invention;

FIGS. 7 and 8 are schematic views of an embodiment of the present invention showing the display module changing its pitch angle;

FIG. 9 is a schematic view of an embodiment of the present invention which takes a disk as the indicating device; and

FIGS. 10 and 11 are schematic views of an embodiment of the present invention showing the display module changing its bilateral angel.

### DETAILED DESCRIPTION OF THE PREFERRED EMBODIMENT

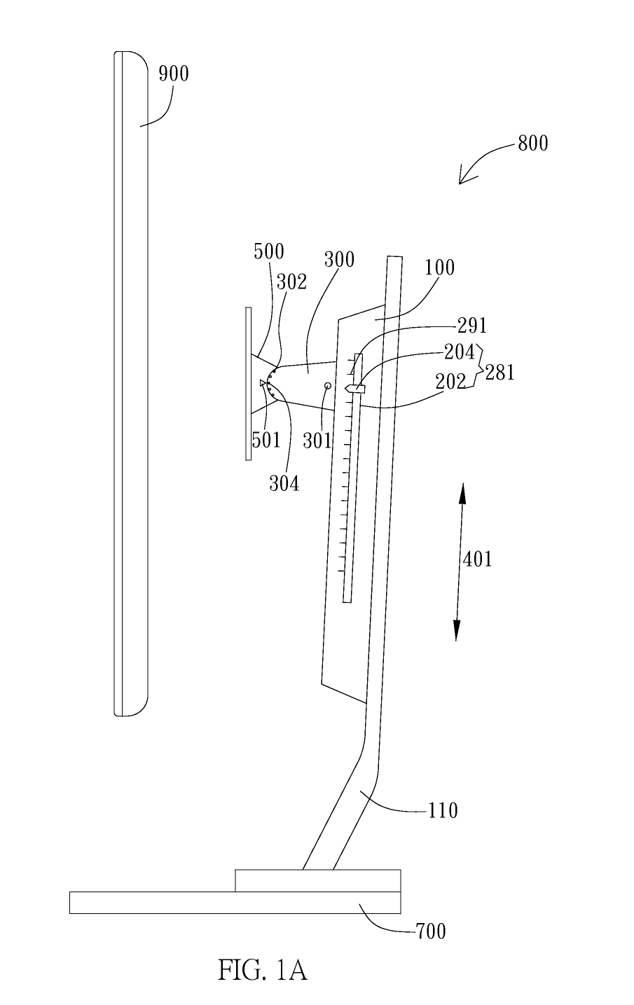

As the embodiment shown in FIG. 1A, the display supporting device 800 of the present invention is for supporting a display module 900. The display module 900 is preferably a LCD display or a plasma display. The display module 900 stands on a desk, a cabinet, or a table by the supporting of the display supporting device 800 for a user to watch.

As the embodiment shown in FIG. 1A, the display supporting device 800 includes a stand 100, a supporting arm 300 served as a moving part, and an indicating device 281. The supporting arm 300 is disposed on the stand 100, wherein the supporting arm 300 is movable between a first position and a second position relative to the stand 100 for connecting the display module 900 with the stand 100. More particularly, in this embodiment, a supporting bracket 110 and a base 700 are regarded as the stand 100, wherein the supporting arm 300 is movable along a straight line in direction 401 relative to the supporting bracket 110 of the stand 100.

As the embodiment shown in FIG. 1A, the indicating device 281 includes a guide groove 202 and an indicating part 204. The guide groove 202 is disposed on the stand 100 along a moving path of the moving part relative to the stand 100, i.e. disposed on the supporting bracket 110 along the direction 401. The indicating part 204 is disposed in the guide groove 202 and is movable along the guide groove 202. More particularly, as shown in FIG. 1B, the indicating part 204 preferably has elastic arms 214. Therefore, as shown in FIG. 1C, when the indicating part 204 is disposed in the guide groove 202, the elastic arms 214 engage with the inner wall of the guide groove 202 by the elastic force, hence it makes the indicating part 204 stay in a specific position of the guide groove 202.

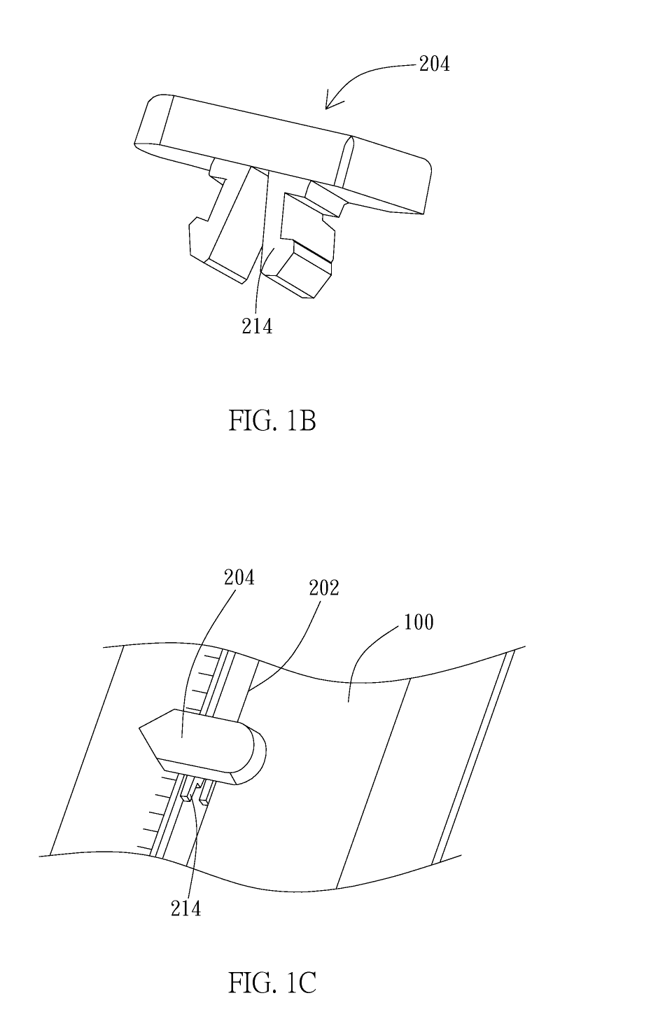

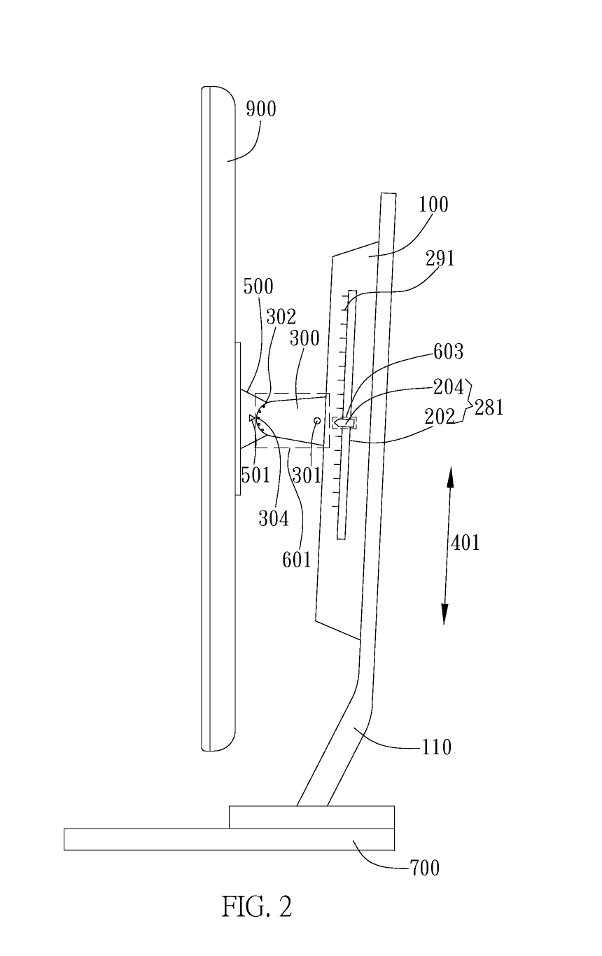

As shown in FIG. 2, the indicating device 281 is disposed on the stand 100 for indicating the position of the supporting arm 300 relative to the stand 100. More particularly, if the height of the display module 900 is preferred when the supporting arm 300 moves to a first position 601, the user can move the indicating part 204 of the indicating device 281 to a third position 603 corresponding to the first position 601 and make the indicating part 204 stop at the third position 603 for indicating the position of the supporting arm 300 relative to the stand 100 and recording the position of the display module 900 corresponding to the first position 601. As shown in FIG. 3, when the height of the display module 900 has been changed to a position corresponding to a second position 602 at which the supporting arm 300 stays due to someone else's use or other reasons, the user merely needs to pull down the display module 900 along with the supporting arm 300 and makes the supporting arm 300 correspond to the indicating part 204 which stays at the third position 603, so that the display module 900 is brought back to the first position 601 as shown in FIG. 2 as recorded.

As shown in FIGS. 2-3, the guide groove 202 further includes graduations 291 for the user to record the position of indicating part 204 after moving it, wherein it can avoid a situation that no reference could be taken for adjusting the display module 900 back to the first position 601 due to an unexpected moving of the indicating part 204. The supporting arm 300 further includes a mark 301 disposed adjacent to the indicating device 281, wherein the indicating device 281 takes the mark 301 as a reference to indicate the position of the supporting arm 300 relative to the stand 100. More particularly, when indicating the position of the supporting arm 300 relative to the stand 100, the user can move the indicating part 204 to align with the mark 301 for reducing the error of indication.

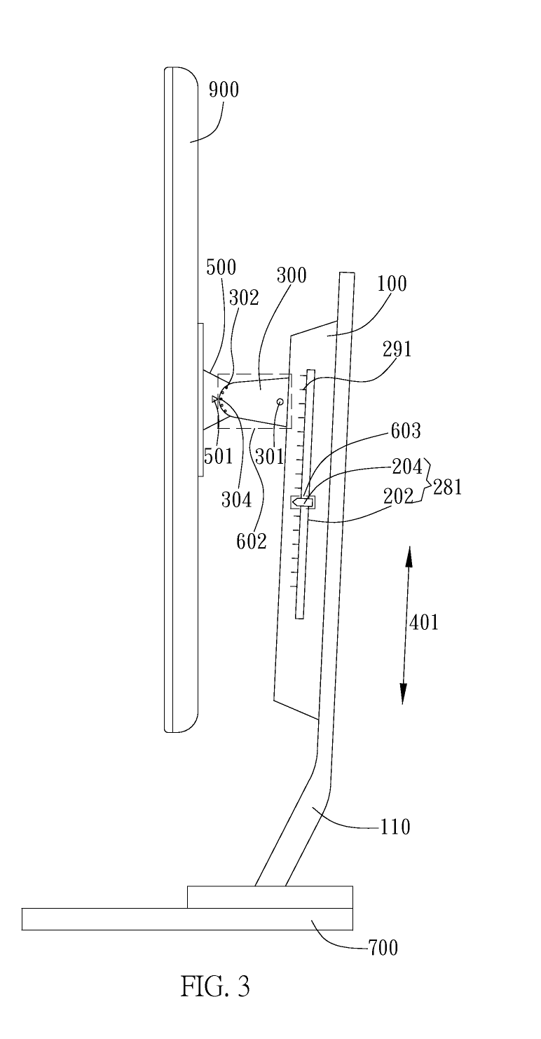

In the above embodiment, the indicating device 281 includes the guide groove 202 and the indicating part 204. In a different embodiment, however, the indicating device can be varied depending on the manufacturing and using requirements. As the embodiment shown in FIG. 4A, the indicating device 282 includes a guide rail 201 and an indicating part 203. The guide rail 201 is disposed on the stand 100 along the moving path of the supporting arm 300 relative to the stand 100, i.e. disposed on the supporting bracket 110 along the direction 401. More particularly, as the embodiment shown in FIG. 4B, the indicating part 203 is sleeved on the guide rail 201, wherein the indicating part 203 is movable along the guide rail 201 and stops at a third position 603 shown in FIG. 4A for indicating the position of the supporting arm 300 relative to the stand 100 and recording the indicated position of the display module 900 corresponding to the first position 601. The guide rail 203 further includes graduations 292.

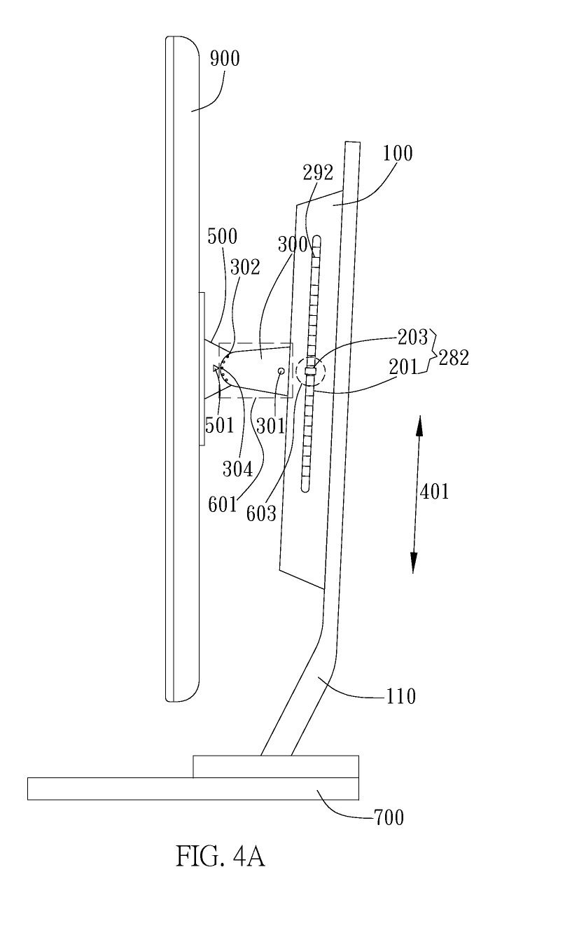

As the embodiment shown in FIG. 5, the indicating device 283 includes a plurality of sockets 206 and an indicating part 208. The plurality of sockets 206 are disposed on the stand 100 along a moving path of the supporting arm 300 relative to the stand 100, i.e. disposed on the supporting bracket 110 along the direction 401. The indicating part 208 is preferably a pin that can be inserted in one of the sockets 206 for indicating the position of the supporting arm 300 relative to the stand 100 and recording the indicated position of the display module 900 corresponding to the first position 601.

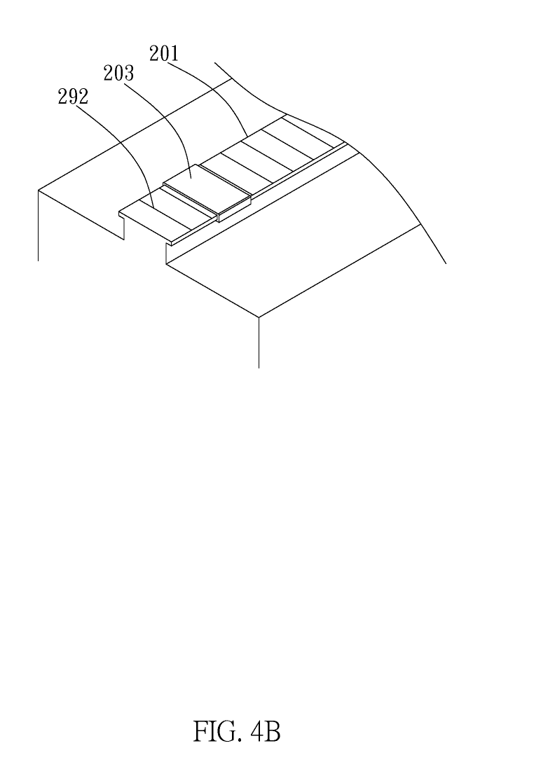

As the embodiment shown in FIG. 6, the indicating device 284 includes a magnetic bar 205 and an indicating part 207. The magnetic bar 205 is disposed on the stand 100 along a moving path of the supporting arm 300 relative to the stand 100, i.e. disposed on the supporting bracket 110 along the direction 401. The indicating part 207 has magnetic permeability, wherein the indicating part 207 can be magnetically drawn on the magnetic bar 205 and stops at a third position 603 for indicating the position of the supporting arm 300 relative to the stand 100 and recording the indicated position of the display module 900 corresponding to the first position 601. The magnetic bar further includes graduations 293.

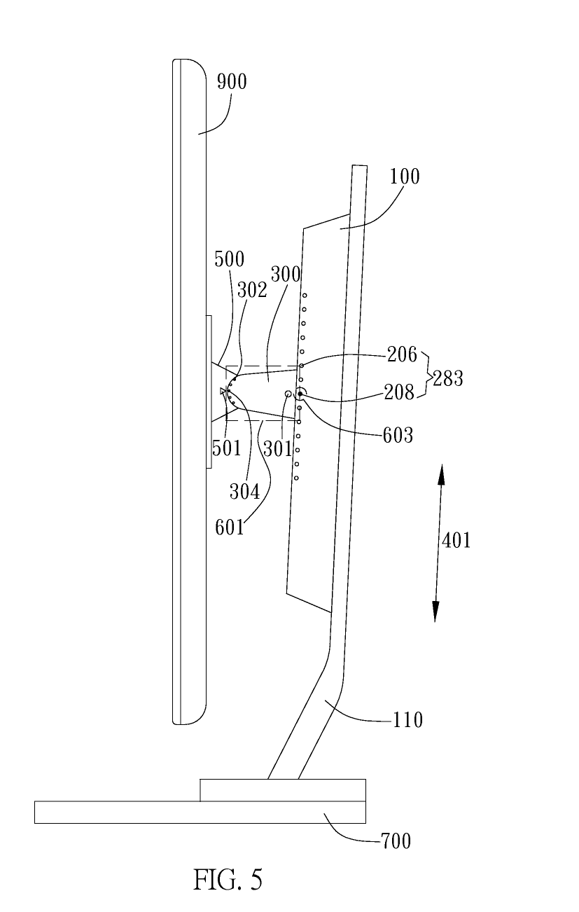

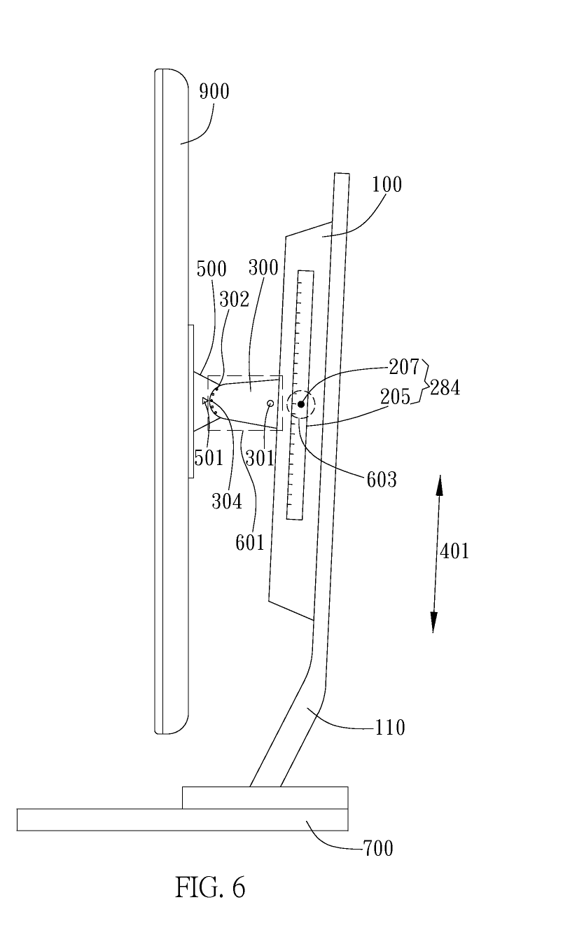

In the above embodiments, the supporting arm 300 is movable along a straight line relative to the stand 100. In a different embodiment, however, the moving direction or the moving path of the supporting arm 300 relative to the stand 100 can be varied depending on the design and using requirements. As the embodiments shown in FIGS. 7 and 8, the display supporting device 800 includes a stand 100, a connecting part 500 served as a moving part, and an indicating device 380. The supporting arm 300 is disposed on the stand 100 for connecting the display module 900 with the stand 100, wherein the supporting arm 300 is rotatable along the direction 402. More particularly, in this embodiment, the supporting bracket 110, the supporting arm 300, and the base 700 are regarded as the stand 100, wherein the connecting part 500 is regarded as the moving part and is movable along a curved line corresponding to the stand 100.

As shown in FIG. 7, if the pitch angle of the display module 900 is preferred when the connecting part 500 rotates to a first position 611 relative to the supporting arm 300, the user can move the indicating part 304 of the indicating device 380 to a third position 613 corresponding to the first position 611 and make the indicating part 304 stop at the third position 613 (e.g. inserting a pin served as the indicating part 304 into a corresponding socket 302) for indicating the angle of the connecting part 500 relative to the stand 100 and recording the angle of the display module 900 corresponding to the first position 611. As shown in FIG. 8, when the pitch angle of the display module 900 has been changed to a position corresponding to a second position 612 at which the connecting part 500 stays due to someone else's use or other reasons, the user merely needs to rotate the display module 900 along with the connecting part 500 along the direction 402 and makes the mark 501 of the connecting part 500 correspond to the indicating part 304 which stays at the third position 613, as shown in FIG. 7, so that the display module 900 is brought back to the first position 611.

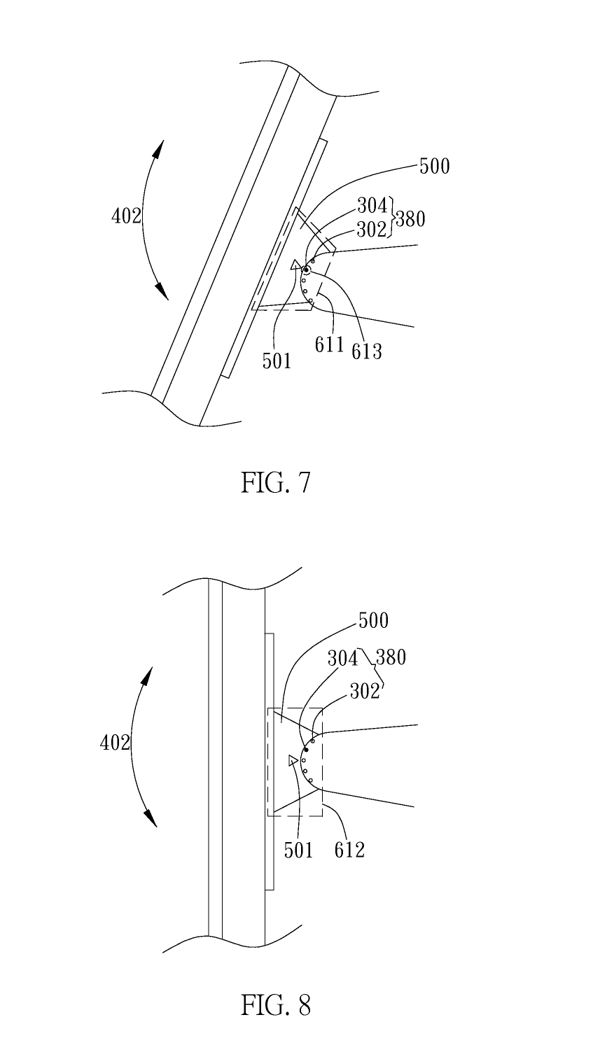

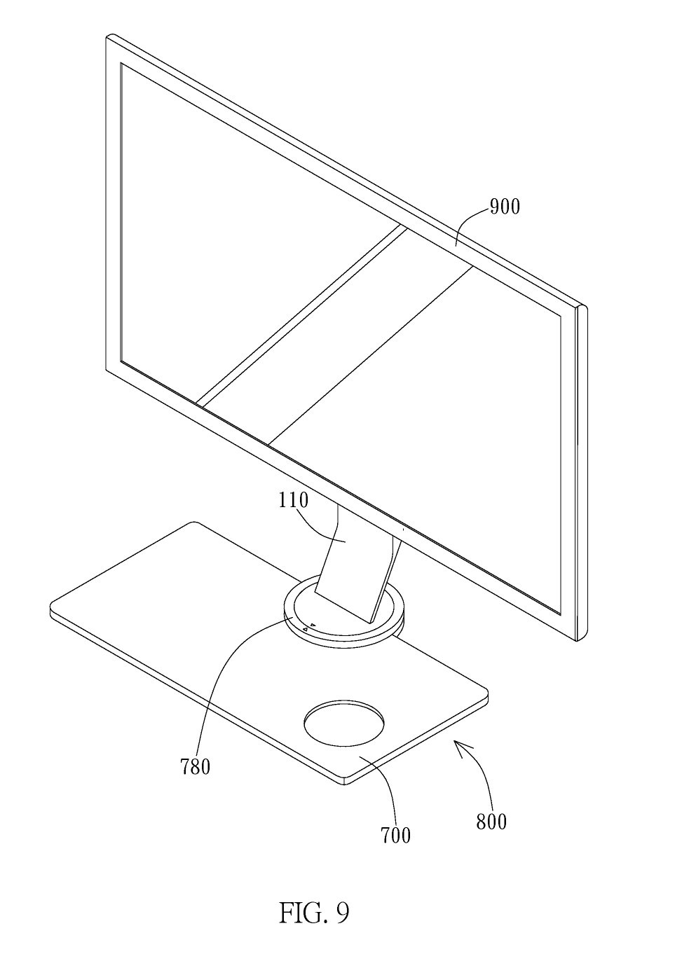

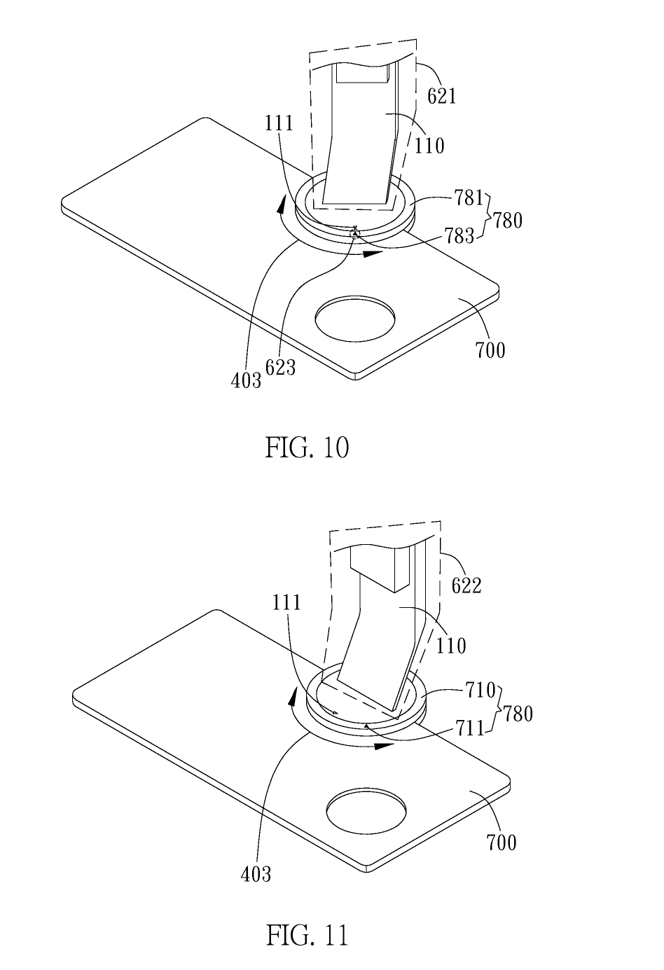

As the embodiments shown in FIGS. 9-11, the display supporting device 800 includes a base 700 served as a stand 100, a supporting bracket 110 served as a moving part, and an indicating device 780. The supporting bracket 110 is disposed on the base 700 for connecting the display module 900 with the base 700, wherein the supporting bracket 110 is rotatable along the direction 403. As shown in FIG. 10, if the bilateral angle of the display module 900 is preferred when the supporting bracket 110 rotates to a first position 621 relative to the base 700, the user can rotate a turntable 781 of the indicating device 780 to a third position 623 corresponding to the first position 621 and make an indicating part 783 of the turntable 781 stop at the third position 623 (i.e. rotating the turntable 781 to make the indicating part 783 correspond to the mark 111 of the supporting bracket 110 in this embodiment) for indicating the bilateral angle of the supporting bracket 110 relative to the base 700 and recording the bilateral angle of the display module 900 corresponding to the first position 621. As shown in FIG. 11, when the bilateral angle of the display module 900 has been changed to a position corresponding to a second position 622 at which the supporting bracket 110 stays due to someone else's use or other reasons, the user merely needs to rotate the display module 900 along with the supporting bracket 110 along the direction 403 and makes the mark 111 of the supporting bracket 110 correspond to the indicating part 783 which stays at the third position 623, as shown in FIG. 10, so that the display module 900 is brought back to the first position 621.

Upon the whole, the indicating device is disposed on the stand for indicating the position of the moving part relative to the stand. The indicating device is able to record the rotating angle or moving distance of the moving part, so that the display can be adjusted back to a recorded angle or position in accordance with the indicating device when the display module changes its angle or position. Thus, the user's adjusting (e.g. the above described height, pitch angle, and bilateral angel) time can be reduced, increasing the convenience in use.

Although the preferred embodiments of the present invention have been described herein, the above description is merely illustrative. Further modification of the invention herein disclosed will occur to those skilled in the respective arts and all such modifications are deemed to be within the scope of the invention as defined by the appended claims.

What is claimed is:

1. A display supporting device for supporting a display module, comprising:
a stand;
a moving part disposed on the stand, wherein the moving part is movable between a first position and a second position relative to the stand for connecting the display module with the stand; and
an indicating device disposed on the stand for indicating the position of the moving part relative to the stand;
wherein the indicating device is able to record the rotating angle or moving distance of the moving part, the display module can be adjusted back to a recorded angle or position in accordance with the indicating device when the display module changes its angle or position.

2. The display supporting device of claim 1, wherein the moving part is movable along a straight line relative to the stand.

3. The display supporting device of claim 1, wherein the moving part is movable along a curved line relative to the stand.

4. The display supporting device of claim 1, wherein the moving part is rotatable relative to the stand.

5. The display supporting device of claim 1, wherein the indicating device includes:
a guide groove disposed on the stand along a moving path of the moving part relative to the stand; and
an indicating part disposed in the guide groove, wherein the indicating part is movable along the guide groove and stops at a third position for indicating the position of the moving part relative to the stand and recording the indicated angle or position of the display module corresponding to the first position.

6. The display supporting device of claim 5, wherein the guide groove further includes graduations.

7. The display supporting device of claim 1, wherein the indicating device includes:
a guide rail disposed on the stand along a moving path of the moving part relative to the stand; and
an indicating part sleeved on the guide rail, wherein the indicating part is movable along the guide rail and stops at a third position for indicating the position of the moving part relative to the stand and recording the indicated angle or position of the display module corresponding to the first position.

8. The display supporting device of claim 7, wherein the guide rail further includes graduations.

9. The display supporting device of claim 1, wherein the indicating device includes:
a plurality of sockets disposed on the stand along a moving path of the moving part relative to the stand; and
an indicating part, wherein the indicating part can be inserted in one of the sockets for indicating the position of the moving part relative to the stand and recording the indicated angle or position of the display module corresponding to the first position.

10. The display supporting device of claim 1, wherein the indicating device includes:
a magnetic bar disposed on the stand along a moving path of the moving part relative to the stand; and
an indicating part having magnetic permeability, wherein the indicating part can be magnetically drawn on the magnetic bar and stops at a third position for indicating the position of the moving part relative to the stand and recording the indicated angle or position of the display module corresponding to the first position.

11. The display supporting device of claim 10, wherein the magnetic bar further includes graduations.

12. The display supporting device of claim 1, wherein the moving part further includes a mark disposed adjacent to the indicating device, wherein the indicating device takes the mark as a reference to indicate the position of the moving part relative to the stand.
